(19) United States
(12) Patent Application Publication
(10) Pub. No.: US 2010/0203736 A1
(43) Pub. Date: Aug. 12, 2010

(54) Plasma Processing Method

(75) Inventors: Takamasa ICHINO, Kudamatsu (JP); Kenji MAEDA, Koganei (JP); Kenetsu YOKOGAWA, Tsurugashima (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi High-Technologies Corporation

(21) Appl. No.: 12/414,742

(22) Filed: Mar. 31, 2009

(30) Foreign Application Priority Data
Feb. 12, 2009 (JP) 2009-029252

(51) Int. Cl. H01L 21/3065

(52) U.S. Cl. 438/710; 257/E21.218

(57) ABSTRACT

There is provided a plasma processing method which controls a bias power to be constant without affecting the bias power supplied to a wafer, even if a part of a bias power supplied to a wafer is divided and supplied to a focus ring, and does not change the etching characteristic of the entire substrate to be processed. A high-frequency bias power supplied to a focus ring is changed by controlling the impedance control circuit according to the waste quantity of the focus ring that is wasted by the plasma processing. On the other hand, the high-frequency bias power supplied to the specimen support is controlled to the given high-frequency bias power by controlling the output of the high-frequency bias power supply.

### BACKGROUND OF THE INVENTION

1. Field of the Invention

The present invention relates to a plasma processing method for performing plasma processing on a substrate to be processed which is mounted on a specimen support by supplying a gas into a vacuum chamber. More particularly, the present invention relates to a plasma processing method which is capable of suppressing a phenomenon that holes occurring in a wafer end are tilted when, for example, a pattern on the substrate to be processed is contact holes having a high aspect ratio in dry etching used for etching an interlayer insulating film, etc., among etching processes using the plasma processing.

2. Description of the Related Art

In the recent semiconductor technologies, a memory device such as a DRAM (dynamic random access memory) is being advanced toward a direction along which holes of the high aspect ratio are formed in order to hold a capacitor capacity, and the height of the capacitor is increased as integration is advanced. In the International Technology Roadmap for Semiconductors, the aspect ratio will become as very high as about 50 in 2011. Further, in order to improve the yield, in a large-diameter wafer which is φ 300 mm or higher, a wafer has been required to be uniformly processed in an area within 3 mm from an end thereof. In the future tendency, it is desirable that a value of 3 mm becomes gradually smaller, and it becomes necessary to make excellent produces even from the wafer end 0 mm as the ultimate request.

Subsequently, a dry etching method will be described. Dry etching is a technique by which an etching gas introduced into a vacuum chamber is put into plasma by supplying a high-frequency power from the external, reactive radical or ions generated in plasma are made to react with a wafer with high precision, whereby a film to be processed is selectively etched with respect to a mask material represented by a resistor, or a wiring layer or an underlying substrate which is located under via holes, contact holes, capacitors, or the like.

In the formation of the above via holes, contact holes, or capacitors, a mixture gas of a rare gas represented by Ar with oxygen or the like is introduced into fluorocarbon based gas such as CF₄, CHF₃, C₂F₆, C₃F₆O, C₄F₈, C₅F₈, or C₄F₆ as a plasma gas, plasma is developed in a pressure region of 0.5 Pa to 10 Pa, and an ion energy applied to the wafer is accelerated from 0.5 kV to 5.0 kV by a peak to peak value (wafer Vpp) of the voltage as a high-frequency bias power that is supplied to the wafer. In this case, there arises a problem on the configuration abnormality of the wafer end.

The configuration abnormality called “tilting” will be described with reference to FIGS. 2A and 2B. FIGS. 2A and 2B show a device configuration of the wafer end at the time of plasma processing, a sheath configuration, and an orbit of ions input to the wafer. When the thickness of a sheath (interface between the sheath and plasma) on a wafer W mounted on a lower electrode 4, and the sheath thickness on a focus ring 7 are equal to each other, ions are input vertically even to the wafer end as shown in FIG. 2A.

However, there has been known that the focus ring 7 is wasted, and its dimensions are changed when plasma processing is repeated by physical waste caused by incidence of ions and chemical reaction. When the height of the focus ring 7 is changed by the waste, the thickness of the sheath is also changed. Therefore, as shown in FIG. 2B, ions are obliquely input to the wafer end with the result that a hole configuration resultantly formed is also obliquely inclined. This phenomenon is tilting which hinders uniform processing (vertical processing) at the end of the wafer, which causes a deterioration in the yield.

To solve the above problem, there has been proposed that an electric power that is supplied to an electrode of the wafer from a high-frequency bias power supply is divided by an impedance adjuster circuit (variable capacity capacitor, or the like), and also supplied to the focus ring, and when the focus ring is wasted, a bias power to the focus ring is changed by the impedance adjuster circuit (power is increased) to keep a uniform plasma sheath surface (sheath/plasma interface) (JP-A 2005-203489).

However, in JP-A 2005-203489, the impedance is originally changed to divide the power supplied to the wafer from the high-frequency bias power supply and supply the divided power to the focus ring. As a result, there arises such a problem that a value of the bias power (voltage in JP-A 2005-203489) applied to the wafer is reduced as much as divided voltage. Because the value of the bias power applied to the wafer greatly affects the etching characteristic of the entire wafer being a substrate to be processed, there arises such a problem that the etching characteristic is changed every time the impedance is adjusted according to the waste of the focus ring, which also greatly affects the yield. Also, in JP-A 2005-203489, the costs of the device are increased because a laser displacement gauge is used for detecting the waste quantity of the focus ring.

### SUMMARY OF THE INVENTION

The present invention has been made in view of the above problems, and therefore an object of the present invention is to provide a plasma processing method in which even if a part of the bias power (wafer power) that is supplied to a wafer (specimen support) is divided and supplied to the focus ring, the bias power applied to the wafer is controlled constantly without any influence, and the etching characteristic of the entire substrate to be processed is not changed.

In the present specification, the constant control of the power permits a range of ±3% of a given power.

Also, the bias power supplied to the wafer may be obtained by directly monitoring the power supplied to the wafer, or monitoring the divided power at another place.

The same is applied to the power supplied to the focus ring.

In order to solve the above problem, according to the present invention, there is provided a plasma processing method for performing plasma processing on a substrate to be processed which is mounted on a specimen support by supplying a gas into a vacuum chamber,

wherein a given high-frequency bias power different from a plasma production high-frequency power is supplied to the specimen support from a high-frequency bias power supply,

wherein the high-frequency bias power output by the high-frequency bias power supply and divided by an impedance adjuster circuit is supplied to a focus ring arranged in the periphery of the substrate to be processed,

wherein according to a consumption of the focus ring consumed by performing the plasma processing, the high-frequency bias power supplied to the focus ring is changed by controlling the impedance adjuster circuit, and

wherein the high-frequency bias power supplied to the specimen support is controlled to the given high-frequency bias power by controlling an output of the high-frequency bias power supply.

According to the present invention, in the plasma processing method described above, a consumption of the focus ring is calculated on the basis of at least the type of plasma processing, the high-frequency power supplied to the specimen support, the high-frequency bias power supplied to the focus ring, or a plasma processing period of time, and

outputs of the impedance adjuster circuit and the high-frequency bias power supply are controlled according to the calculated consumption.

Also, in order to solve the above problem, according to the present invention, there is provided a plasma processing method in which a substrate to be processed is arranged on a specimen support having a focusing ring which is disposed within a vacuum chamber, a processing gas is supplied into the vacuum chamber to generate plasma, and a high-frequency bias power distributed to the specimen support and the focus ring is supplied to process the substrate to be processed,

wherein the high-frequency power applied to the specimen support is held constant according to the consumption of the focus ring consumed by performing the plasma processing on the substrate to be processed, and

wherein the entire high-frequency bias power is so increased as to control the high-frequency power that is supplied to the focus ring.

According to the present invention, in the plasma processing method described above, a relationship between the consumption of the focus ring and a recipe of the plasma processing is obtained in advance, a processing time using the recipe is integrated together to calculate the consumption of the focus ring, and an increase and a distribution of the high-frequency bias power are controlled according to the calculated consumption.

Further, according to the present invention, in any plasma processing method described above, the high-frequency bias power supplied to the specimen support is controlled to be held to an initial power of the given high-frequency bias power by controlling the output of the high-frequency bias power supply.

Further, according to the present invention, in any plasma processing method described above, the high-frequency bias power supply is so controlled as to output a total power of the given high-frequency bias power supplied to the specimen table and the high-frequency bias power supplied to the focus ring which is changed by controlling the impedance adjuster circuit.

According to the present invention, even if the impedance is changed by the impedance adjuster circuit to change the high-frequency bias power supplied to the focus ring, because the high-frequency bias power supplied to the specimen support, that is, a wafer is not changed, the yield can be improved without changing the etching characteristic of the wafer.

Also, since the waste quantity of the focus ring is calculated on the basis of the plasma processing time or the like in advance, and the control is executed according to the waste quantity, it is unnecessary to detect the waste quantity, and the costs of the device are not increased.

### BRIEF DESCRIPTION OF THE DRAWINGS

FIG. 1 is a longitudinal cross-sectional view showing a plasma processing device according to an embodiment of the present invention;

FIGS. 2A and 2B are explanatory diagrams showing the occurrence of tilting which is attributable to the waste of a focus ring, respectively;

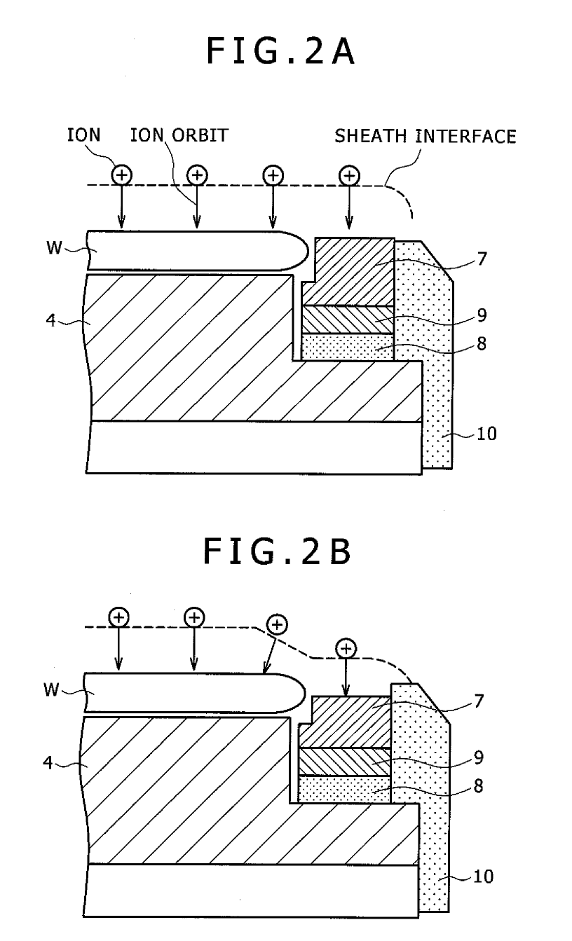

FIGS. 3A and 3B are explanatory diagrams showing a level change in a bias power output, a capacitor capacity, and a wafer power to a discharge time between the conventional example and the embodiment of the present invention, respectively;

FIGS. 4A to 4D are explanatory diagrams showing a power supplied to a sheath interface and respective parts according to the embodiment of the present invention, respectively;

FIG. 5 is a flowchart showing a control procedure according to the embodiment of the present invention; and

FIGS. 6A to 6C are explanatory diagrams showing respective tables for control according to the embodiment of the present invention.

### DETAILED DESCRIPTION OF THE PREFERRED EMBODIMENTS

Hereinafter, a description will be given of an embodiment of the present invention with reference to the accompanying drawings.

In this embodiment, a description will be given of a control method in which an estimated waste quantity of a focus ring is determined according to a plasma processing time (discharge time) in each of plasma processing conditions (the types of plasma processing) (recipe), the capacity control of a capacitor (impedance adjuster circuit), the output control of the bias power supply, and the constant holding control of a supply power to the wafer with respect to the estimated waste quantity are executed to prevent tilting on a wafer end surface and ensure the etching characteristic.

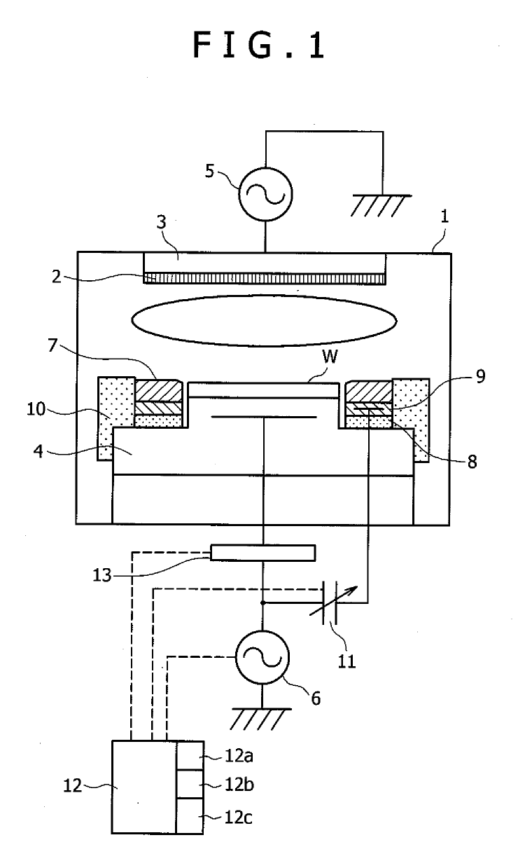

FIG. 1 is a longitudinal cross-sectional view showing a plasma processing device (plasma etching device) used in this embodiment.

The plasma processing device includes a shower plate 2, an upper electrode 3, and a lower electrode 4 serving also as a specimen support on which a wafer W is mounted in a vacuum chamber 1. A high-frequency power for plasma generation is supplied to the upper electrode 3 from a high-frequency power supply 5, and a high-frequency bias power (wafer power) is supplied to the lower electrode 4 from a high-frequency power supply 6. An annular member 7 (hereinafter referred to as “focus ring”), an insulator ring 8, and a conductor ring 9 are located on the outer peripheral end of the lower electrode 4, and a susceptor 10 is arranged on the outer peripheral portions of those members.

The high-frequency bias power supplied from the high-frequency bias power supply 6 is supplied to the lower electrode 4, and simultaneously divided by an impedance adjustor circuit 11 (hereinafter referred to as “variable capacity capacitor”) so as to be also supplied to the focus ring 7 through the conductor ring 9.

Reference numeral 12 denotes control means which controls a bias electric energy of the high-frequency bias power supply 6, and also controls the divided quantity of the bias electric power from the high-frequency bias power supply 6 to the focus ring 7 while changing the capacity of the variable capacity capacitor 11. The control means 12 also includes storage means 12a for recording the type of processing, the processing time (discharge time), or the like in performing the high-frequency plasma processing since a fresh focus ring is installed, as a past actual performance, a table 12b representing the type of processing, the discharge time, and the estimated waste quantity of focus ring corresponding to the type of processing and the discharge time, and a table 12c representative of the capacitor capacity and the power value of the bias power output which are suitable for the subsequent high-frequency plasma processing with respect to the estimated waste quantity.

Reference numeral 13 denotes wafer Vpp detecting means for detecting Vpp of a wafer bias voltage as the high-frequency bias power supplied to the wafer, which is connected to the control means 12.

The high-frequency plasma processing according to this embodiment will be described with reference to FIG. 1. A raw gas is introduced into a vacuum chamber 1 through the shower plate 2 from a gas introduction tube not shown, and a high-frequency power of 200 MHz is supplied to the vacuum chamber 1 from the high-frequency power supply 5 through the upper electrode 3 to generate plasma. A substrate to be processed (wafer) W is put on the lower electrode 4. A high-frequency bias power of 4 MHz is supplied to the lower electrode 4 from the high-frequency bias power supply 6, and ions are drawn by wafer Vpp (peak to peak voltage) developed on the wafer W to execute etching. In this embodiment, a gas mixture of C₄F₆, Ar, and 0₂ is introduced into the vacuum chamber as the raw gas, the pressure is controlled to 4 Pa by a vacuum exhaust system and pressure control means not shown, and a silicon oxide film is etched.

A chuck part (semiconductor wafer holding mechanism) not shown for holding the wafer W is disposed on the central portion of the specimen support and lower electrode 4. For example, an electrostatic chuck is disposed as a chuck mechanism. A surface of the electrostatic chuck for holding the wafer W is made up of a ceramic thin film made of, for example, aluminum nitride, and an aluminum substrate below the ceramic thin film. To the substrate are supplied a power from the high-frequency bias power supply 6, and a DC voltage from a DC voltage power supply through a low-pass filter made up of a choke coil not shown, etc.

Also, the electrostatic chuck is provided with an electrothermal gas supply hole not shown, and for example, He gas is allowed to flow in the electrothermal gas supply hole, thereby making it possible to improve the heat transfer efficiency of the lower electrode 4 and the wafer W. Also, the susceptor made of insulator is located in order to prevent the power supplied to the lower electrode 4 from leaking to the external.

The focus ring 7 is arranged around the lower electrode 4, and the focus ring 7 is made of conductive or insulating material, which is made of silicon in this embodiment. The conductor ring 9 for supplying the distributed output of the high-frequency bias power supply to the focus ring 7 is disposed below the focus ring 7, and the insulator ring 8 for electrically insulating the focus ring 7 and the conductor ring 9 from the lower electrode 4 is disposed below the conductor ring 9.

The high-frequency bias power from the high-frequency bias power supply 6 is divided by the variable capacity capacitor 11, and supplied to the lower electrode 4 and the conductor ring 9, separately. Hereinafter, the power supplied to the lower electrode 4 and the wafer put on the lower electrode 4 is called “wafer power”, and the power supplied to the focus ring 7 is called “focus ring power” (FR power). The impedance is changed by changing the capacity of the variable capacity capacitor 11, thereby making it possible to change the divided ratio of the wafer power and the FR power. The appropriate adjustment of the capacity enables the height of ion sheaths generated on the wafer surface and the focus ring surface to be kept constant so as to suppress tilting even when the focus ring is wasted.

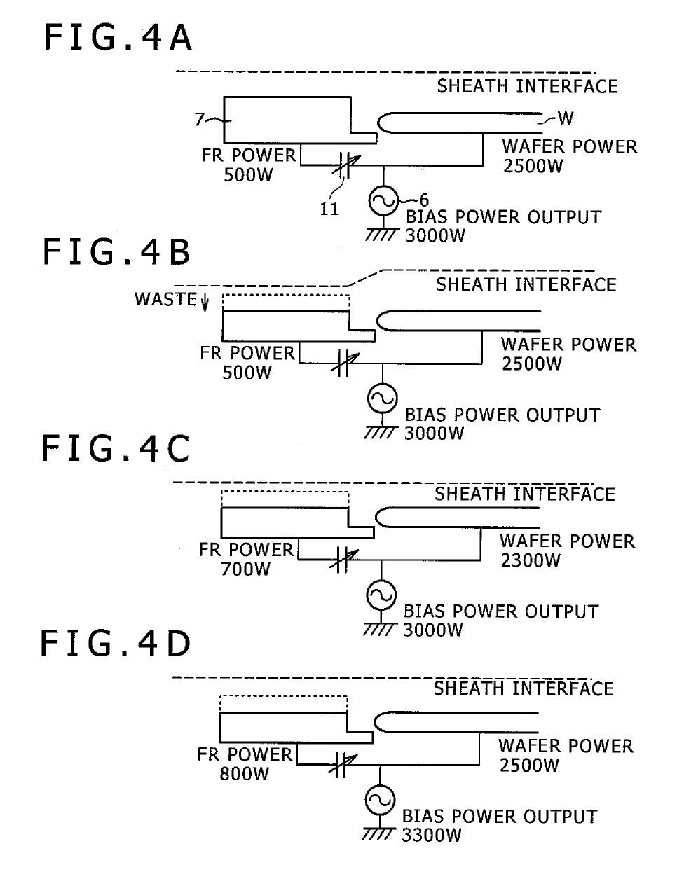

Subsequently, a description will be given of a plasma processing method when the focus ring 7 is wasted with reference to FIGS. 4A to 4D. FIGS. 4A to 4D are for explanation of the wafer power, the FR power, the output power of the bias power supply, and the sheath configuration during the plasma processing in the conventional method and the method of the present invention.

FIG. 4A shows a state of a fresh focus ring. The capacity of the variable capacity capacitor 11 is appropriately set to divide the output 3000 W of the high-frequency bias power supply to the wafer power 2500 W and the FR power 500 W for supply. In this case, the sheath thicknesses of the wafer surface and the focus ring surface are equal to each other, and there arises no problem on tilting.

FIG. 4B shows a state in which the focus ring is wasted through the plasma processing. When the focus ring is wasted, the sheath interface of the focus ring surface becomes as low as the wasted quantity, and produces a step with respect to the sheath interface of the wafer surface. Accordingly, the sheath thickness is different on the outer peripheral end of the wafer, resulting in a problem on tiling.

FIG. 4C shows a case in which the capacitor capacity is changed to vary the ratio of the wafer power and the FR power, thereby eliminating the problem on tilting in the conventional countermeasure. The capacity of the capacitor is controlled to divide the output 3000 W of the high-frequency bias power supply at a ratio of 2300 W of the wafer power and 700 W of the FR power. In this case, because the sheath thickness of the wafer surface and the focus ring surface are equal to each other although being in a low state, it is possible to suppress the occurrence of tilting.

However, there arises a new problem that the wafer power is reduced from 2500 W to 2300 W as compared with that in FIG. 4A, thereby inducing a change in the etching characteristic. Accordingly the etching characteristic is changed every time the capacitor capacity is changed, which greatly affects the etching characteristic of the overall wafer, thereby deteriorating the yield.

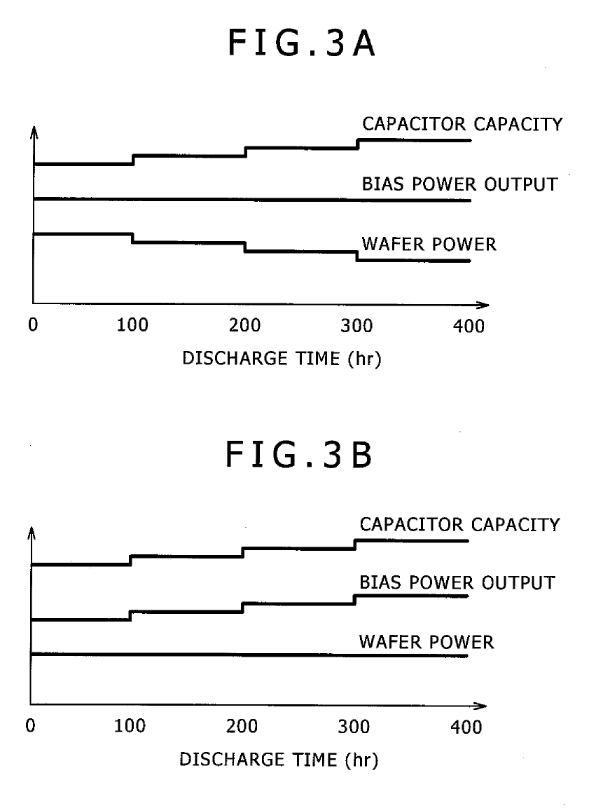

A relationship between the capacitor capacity and the power in the above state will be described with reference to FIGS. 3A and 3B. That is, in the conventional method shown in FIG. 3A, in order to compensate the waste of the focus ring which is attributable to the plasma processing (the processing time is indicated by a discharge time) in the past experiments, the capacitor capacitance is increased to increase the FR power, and control is conducted to make the sheath thicknesses of the wafer surface and the focus ring surface equal to each other. However, in the above method, in order to increase the capacitor capacitance while the bias power output is kept constant, control is made so that the heights of the sheath interfaces become equal to each other in a lower state, and the wafer power is lowered.

Under the above circumstances, in this embodiment, the output power of the bias power supply is increased, and the heights of the sheath interfaces are made equal to each other without changing the wafer power, thereby solving the above problem.

FIG. 4D shows a case in which a method according to this embodiment is applied. In order to compensate the waste of the focus ring 7, control is made so that the capacitor capacitance is increased to increase the FR power while the output power of the bias power supply is increased to hold the wafer power to a given power at the time of first starting the plasma processing (a power in an initial state before the focus ring is wasted). Accordingly, control is made so that the wafer surface and the focus ring surface are entirely equal to each other in a state where the height of the sheath interface is held to the same height as that in the initial state.

The above control will be described with reference to FIGS. 3A and 3B showing a level change in the bias power output, the capacitor capacity, and the wafer power to the discharge time. That is, in the method according to this embodiment shown in FIG. 3B, in order to compensate the waste of the focus ring which is attributable to the plasma processing in the past experiments, when the capacitor capacitance is increased to increase the FR power, the output power of the bias power supply is increased together, so that the wafer power is held to the given power in the initial plasma processing under the control. An increase in the capacitor capacitance and the output power of the bias power supply is conducted at given timing (for example, 100 hours, 200 hours) of the discharge time indicative of the degree of progression of the plasma processing, and the sheath heights of the wafer surface and the focus ring surface are made equal to each other under the control.

The above control according to this embodiment is executed, thereby enabling tilting to be eliminated, and no change in the etching characteristic occurs due to a change in the wafer power. As a result, it is possible to improve the yield of etching over the entire wafer.

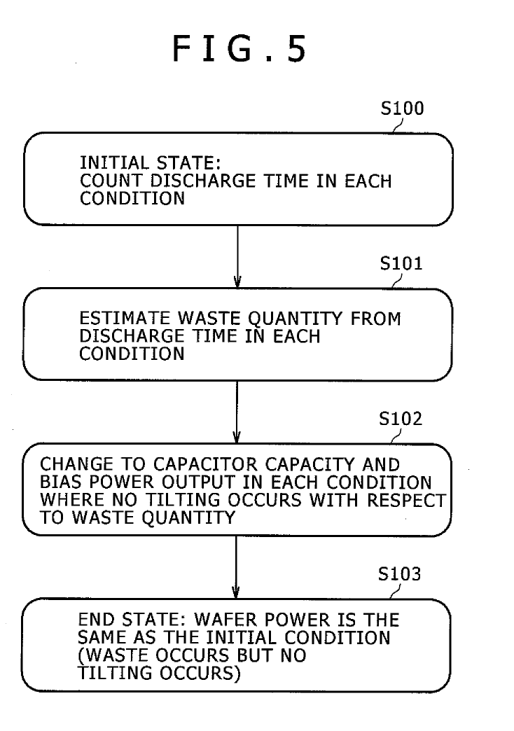

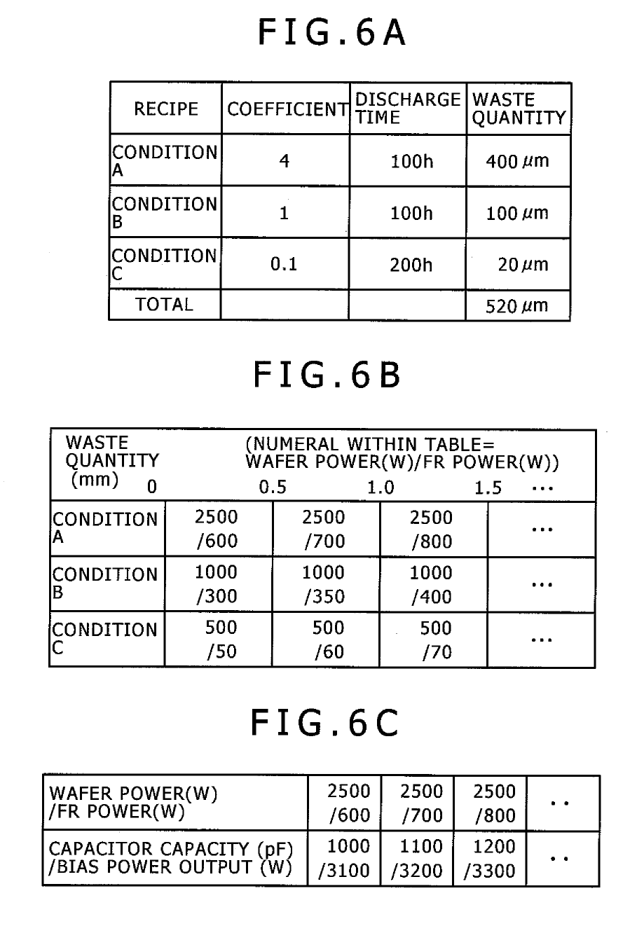

A specific example of this embodiment will be described with reference to an operation flow of FIG. 5 and tables of FIGS. 6A to 6C. FIGS. 6A to 6C are explanatory diagrams of a table 12b and a table 12c incorporated into the control means 12 shown in FIG. 1.

FIG. 6A shows the table 12b of the control means 12 which is representative of the recipe (the type of processing), the discharge time, and the estimated waste quantity of the focus ring corresponding to the recipe and the discharge time. The “recipe” is indicative of the type of high-frequency plasma processing, and the type determined by the wafer power and the FR power. The coefficient represents the wear property of the focus ring under the respective conditions of the recipe. When it is assumed that the plasma processing is executed in the same chamber under the conditions A, B, and C, the waste of the focus ring is high and set to coefficient 4 under the condition A, set to coefficient 1 under the condition B, and difficult and set to coefficient 0.1 under the condition C.

The discharge time in the above table 12b is a past processing time which is sequentially stored in the storage means 12a of FIG. 1 in each of the above conditions. The processing time is also sequentially input to the table 12b. The table 12b includes a formula for computation of the estimated waste quantity (including total waste quantity) of the focus ring based on the discharge time and the coefficient of each of the recipe conditions A, B, and C, and indicates the computation results.

In FIGS. 6B and 5C, the table 12c is divided, and there are shown the capacitor capacities suitable for the future high-frequency plasma processing conditions A, B, and C, and the power values of the bias power outputs with respect to the estimated past waste quantity of the focus ring obtained by the table 12b. FIG. 6B shows the wafer power and the FR power with respect to the total value of the estimated waste quantity, and FIG. 6C shows the preferable capacitor capacity and power value of the bias power output with respect to the wafer power and the FR power.

In this embodiment, control is conducted by the flow of FIG. 5, thereby enabling a state of FIG. 4D to be realized. In Step S100 of FIG. 5, the discharge time in each condition of the respective recipes is counted since the installation of a new focus ring, and then stored in the first storage means 12a as the past discharge time. Then, in S101, the estimated waste quantity wasted in each recipe is calculated from the stored discharge time, and the total estimated waste quantity is calculated from the sum of respective recipes, and shown in the table 12b.

In the table shown in FIG. 6A, discharge for 100 hours, 100 hours, and 200 hours are executed in the conditions A, B, and C of the recipe, respectively. The waste quantities caused by the plasma processing under the respective conditions are 400 μm, 100 μm, and 20 μm, respectively. Hence, the total estimated waste quantity of the focus ring due to the plasma processing for the past at the present time point is 520 μm.

In S102, the preferable capacitor capacity and power value of the bias power output where no tilting occurs during the future plasma processing with respect to the total waste quantity of the focus ring for the past are obtained from the table 12c, and the respective powers are supplied to given places. Because the wafer power becomes the same given power value as that in the initial state, this state does not affect the etching characteristic (S103).

In the table shown in FIG. 6B, since the total waste quantity of the focus ring for the past is 520 μm=0.52 mm, a value of the waste quantity 0.5 mm may be referred to. When the future plasma processing is executed under the condition A, the respective power values in a frame where the condition A and the waste quantity 0.5 mm cross each other are required. That is, the capacitor capacity and the output power value of the bias power supply may be so adjusted as to meet the wafer power of 2500 W and the FR power of 700 W. The capacitor capacity and the output power value of the bias power supply are 1100 pF and 3200 W in correspondence with the wafer power 2500 W and the FR power 700 W, respectively, as shown in the table of FIG. 6C.

The control means 12 sets the variable capacity capacitance 11 and the high-frequency bias power supply 6 to the above values, respectively, and executes preparatory control for high-frequency plasma processing under the future condition A.

The table 12b is created on the basis of the plasma processing under the respective conditions, the coefficient, and the material of the focus ring in advance. Also, the table 12c is created on the basis of the capacitor capacities and the power values of the bias power supply under the respective conditions in advance, and does not increase the costs in the hardware fashion.

Instead of the above table, control may be conducted by using a configuration in which the wafer power and FR power being the future plasma processing conditions are merely input to obtain the preferable capacitor capacity and output power of the bias power supply. This case is an input method suitable for the user of the plasma processing device.

The present invention has been described above with reference to the embodiment. The present invention is not limited by the plasma source, the kind of gas, or the like. That is, the present invention can be applied to an inductively coupled plasma source, a magnetic field microwave plasma source, or the like. The present invention can be also applied to a device of the type where two kinds of frequencies are superimposed on each other and added to the lower electrode. In this case, it is preferable that the present invention is applied to lower one of two kinds of frequencies. Further, in this embodiment, as a guide of control, the wafer power is used, and the output power of the bias power supply is controlled. However, even when the wafer power can be replaced with Vpp (peak to peak voltage) of the wafer bias voltage or the effective value Vrms of the voltage, the same advantages can be expected.

Also, the coefficient for obtaining the waste quantity related to the discharge time in each of recipes is set as constant, however, may be a function that changes according to the waste quantity, or may be a constant that changes according to the waste quantity. Further, the coefficient may be a function of the FR power which changes according to the waste.

Further, it is expected that the temperature increases, and the waste quantity changes as the FR power is increased. In this case, the waste quantity may be multiplied by an additional coefficient, or more preferably there may be provided a mechanism that enables the FR temperature to be controlled to a given temperature.

What is claimed is:

1. A plasma processing method for performing plasma processing on a substrate to be processed which is mounted on a specimen support by supplying a gas into a vacuum chamber, the method comprising the steps of:
supplying a given high-frequency bias power different from a plasma production high-frequency power to the specimen support from a high-frequency bias power supply,
supplying the high-frequency bias power output by the high-frequency bias power supply and divided by an impedance adjuster circuit to a focus ring arranged in the periphery of the substrate to be processed;
according to a consumption of the focus ring consumed by performing the plasma processing,
changing the high-frequency bias power supplied to the focus ring by controlling the impedance adjuster circuit; and
controlling the high-frequency bias power supplied to the specimen support to the given high-frequency bias power by controlling an output of the high-frequency bias power supply.

2. The plasma processing method according to claim 1,
wherein a consumption of the focus ring is calculated on the basis of at least the type of plasma processing, the high-frequency power supplied to the specimen support, the high-frequency bias power supplied to the focus ring, and a plasma processing period of time, and
wherein outputs of the impedance adjuster circuit and the high-frequency bias power supply are controlled according to the calculated consumption.

3. A plasma processing method in which a substrate to be processed is arranged on a specimen support having a focusing ring which is disposed within a vacuum chamber, a processing gas is supplied into the vacuum chamber to generate plasma, and a high-frequency bias power distributed to the specimen support and the focus ring is supplied to process the substrate to be processed, the method comprising the steps of:
hold constant the high-frequency power applied to the specimen support according to the consumption of the focus ring consumed by performing the plasma processing on the substrate to be processed; and
increasing the entire high-frequency bias power so as to control the high-frequency power that is supplied to the focus ring.

4. The plasma processing method according to claim 3, wherein a relationship between the consumption of the focus ring and a recipe of the plasma processing is obtained in advance, a processing time using the recipe is integrated together to calculate the consumption of the focus ring, and an increase and a distribution of the high-frequency bias power are controlled according to the calculated consumption.
